(19) United States
(12) Patent Application Publication
(10) Pub. No.: US 2004/0036496 A1
(43) Pub. Date: Feb. 26, 2004

(54) Electronic load simulation circuit with serially connected impedance element

(76) Inventors: Daniel Liu, Taipei Hsien (TW); Dragon Chang, Shindian City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/223,302

(22) Filed: Aug. 20, 2002

(51) Int. Cl. G01R 31/26

(52) U.S. Cl. 324/769

(57) ABSTRACT

An electronic load simulation circuit includes a current detection resistor for connection with positive and negative terminals of a power source device to be tested. A power transistor is connected between the current detection resistor and the positive terminal of the power source device. The gate of the power transistor is connected to an output of an operational amplifier. A negative input of the operational amplifier is connected to a reference current setting unit. A serially connected impedance element having a resistance much larger than the impedance of the power transistor is connected between the power transistor and the power source device whereby a major portion of the power supplied from the power source device is taken by the serially connected impedance element with only a minor portion being taken by the power transistor.

### BACKGROUND OF THE INVENTION

1. Field of the Invention

The present invention relates generally to a circuit for simulation of electronic load for a power source device to be tested, and in particular to an electronic load simulation circuit having a serially connected impedance element.

2. Description of the Prior Art

Devices or circuits for simulating an electronic load in testing a power source device are well known in the art of electronics. An example of the electronic load simulation device is illustrated in U.S. Pat. No. 6,218,853 B1. Conventionally, an electronic load simulation circuit generally comprises a power transistor and a current detection resistor connected in serial which is then connected to the power source device to be tested. An operational amplifier that has a negative input receiving a reference current signal is connected to the gate of the power transistor for controlling the power transistor. A feedback circuit is connected to the current detection resistor for feeding a signal corresponding to the current flowing through the current detection resistor back to the operational amplifier.

The current detection resistor that is connected in serial with the power transistor is for detection of the magnitude of the current flowing out of the power source device to be tested. The detected magnitude of the current can then be further processes for desired purposes. Thus, the resistance of the current detection resistor is commonly very small.

Since the potential of the tested power supply is applied through the power transistor and the current detection resistor, most of the power that is supplied from the power source device is taken by the power transistor when the power transistor is conducted on. This causes a great amount of heat in the power transistor. Practically, a heat dissipation element is added to the power transistor to remove the heat so generated in order to protect the power transistor. Alternatively, a power transistor of high rating power can be adapted. This increases the overall cost of the simulation circuit.

Further, for test of large power or large current, the simulation circuit comprises a number of circuits connected in parallel and each circuit requires a heat dissipation element. This causes a significant increase of overall costs.

Further, a surge may unexpectedly happen at the very moment when the power transistor is conducted on/off because the small resistance of the current detection resistor. Such a surge causes noises and potential damages to the electronics of the simulation circuit.

Thus, it is desired to have an electronic load simulation circuit that eliminates the problems discussed above.

### SUMMARY OF THE INVENTION

A primary object of the present invention is to provide a control circuit for an electronic load simulation device comprising a serially connected impedance element for protection of the circuit.

Another object of the present invention is to provide an electronic load simulation circuit comprising a serially connected impedance element capable of suppressing surges.

A further object of the present invention is to provide an electronic load simulation circuit of low costs wherein power transistor of lower rating value can be used.

To achieve the above objects, in accordance with the present invention, there is provided an electronic load simulation circuit comprising a current detection resistor for connection with positive and negative terminals of a power source device to be tested. A power transistor is connected between the current detection resistor and the positive terminal of the power source device to function as a switch for selectively allowing current from the power source device to flow through the current detection resistor. The gate of the power transistor is connected to an output of an operational amplifier. A negative input of the operational amplifier is connected to a reference current setting unit. A differential amplifier is connected to the current detection resistor and has an output applied to the negative input of the operational amplifier to control the magnitude of the current from the power source device. A serially connected impedance element having a resistance much larger than the impedance of the power transistor is connected between the power transistor and the power source device whereby a major portion of the power supplied from the power source device is taken by the serially connected impedance element with only a minor portion being taken by the power transistor. This reduces the load of the power transistor and thus allowing the power transistor to have a small rating power and thus low costs.

### BRIEF DESCRIPTION OF THE DRAWINGS

The present invention will be apparent to those skilled in the art by reading the following description of preferred embodiments thereof, with reference to the attached drawings, in which:

FIG. 1 is a control circuit diagram of electronic load simulation device in accordance with a first embodiment of the present invention; and

FIG. 2 is a control circuit diagram of an electronic load simulation device in accordance with a second embodiment of the present invention.

### DETAILED DESCRIPTION OF THE PREFERRED EMBODIMENTS

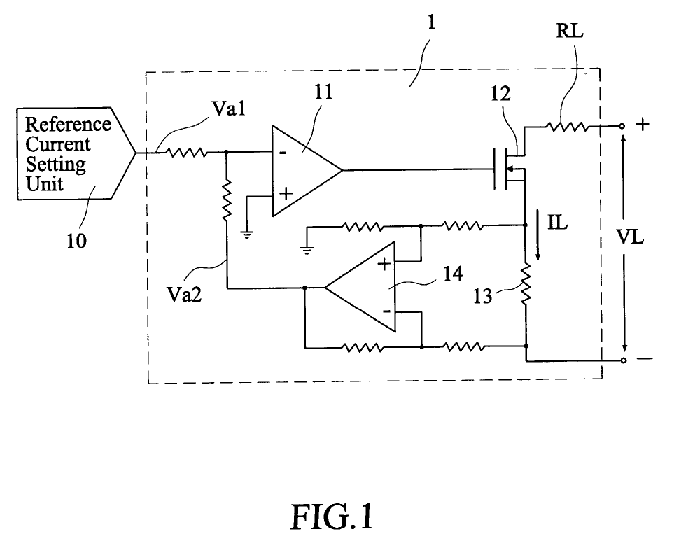

With reference to the drawings and in particular to FIG. 1, an electronic load simulation device comprises a control circuit, generally designated with reference numeral 1, comprising a first operational amplifier 11 having an output end connected to a gate electrode of a power transistor 12, such as a MOSFET (Metal Oxide Silicon Field-effect-transistor). A current detection element 13 connected between a drain electrode of the power transistor 12 and a negative terminal of a power source device VL to be tested. A positive terminal of the power source device VL is connected to a source electrode of the power transistor 12 via a serially connected impedance element RL. The first operational amplifier 11 is capable of generating a control signal to control conduction of the power transistor 12. The power transistor 12 serves as a switch element of the electronic load simulation device for selectively conducting a test current IL from the power source device VL through the current detection element 13 or cutting off the test current IL.

A differential amplifier 14 is incorporated in the control circuit 1 and is connected across the current detection element 13 for detecting the current IL and then generating the detected current signal in correspondence to the current IL that actually flows through the current detection element 13.

A reference current setting unit 10 provides or sets a reference value Va1 for the test current. Alternatively, the reference current setting unit 10 is replaced by a digital circuit or a microprocessor based circuit that receives an external signal and generates a digital signal in response to the external signal, the digital signal being processed by a digital-to-analog converter for conversion of the digital signal into the reference value Va1 for the test current.

An analog signal representing or corresponding to the reference value Va1 is applied to the negative input of the first operational transistor 11 and in response thereto, the first operational transistor 11 generates a control signal at its output. The control signal is able to turn on the power transistor 12. The test current IL then flows from the power source device VL through the current detection element 13 that is connected to the drain electrode of the power transistor 12 and detected thereby. In the embodiment illustrated, the current detection element 13 comprises a resistor having small resistance. The test current IL is then amplified by the differential amplifier 14. A current differential signal that is generated at an output of the differential amplifier 14 is fed to the negative terminal of the first operational amplifier 11 as a feedback signal of the actual value Va2 of the tested current.

In accordance with the present invention, a serially connected impedance element RL is connected between the source electrode of the power transistor 12 and the positive terminal of the power source device VL. In the embodiment illustrated, the serially connected impedance element RL comprises a resistor having a resistance of for example about 100 ohms. The resistance of the serially connected impedance element RL can be of any value that is much greater than the impedance of the power transistor 12, which is generally around 0.1 ohms.

The serially connected resistor RL of the present invention functions to take a major energy of the power supplied from the power source device VL, while the power transistor 12 only takes a small energy. Theoretically, by properly selecting the resistor RL, the power transistor 12 takes almost no power from the power source device VL. Thus, power transistor that has a low rating power value and thus low costs can be adapted in the circuit 1 for reduction of costs.

The serially connected impedance element RL also functions to suppress surges caused at the very moment when the power transistor 12 is conducted ON or OFF. Thus, damage caused by such surges to the electronics of the circuit 1 and even the electronic load simulation device can thus be effectively eliminated.

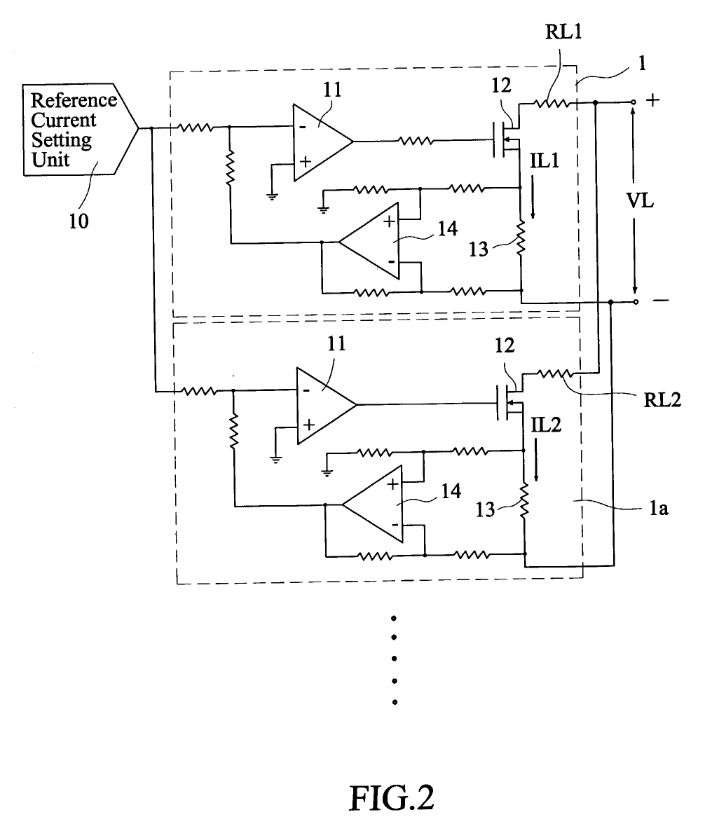

FIG. 2 shows a modification of the control circuit 1 of FIG. 1. The circuit of FIG. 2 comprises a primary control circuit 1 and at least one parallelly connected control circuit la connected in parallel for test of a larger electronic load. A common reference current setting unit 10 is connected to both circuits 1, 1a for setting the value of the test current. The power source device VL is connected to current detection resistors 13 of both circuits 1, 1a whereby components IL1, IL2 of the test current IL are respectively flowing through the current detection resistors 13 of the control circuits 1, 1a. The power transistors 12 that function as a switch of each circuit 1, 1a are connected to the positive terminal of the power source device VL via a serially connected impedance element RL1, RL2. The resistances of the resistors RL1, RL2 are selected in accordance with the current components IL1, IL2.

To this point, it is apparent that the electronic load simulation circuit of the present invention has a simple structure and thus low costs, while providing excellent operation safety.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A control circuit for an electronic load simulation device, comprising:
switching means having a first end and a second end, having an intrinsic impedance when conducted;
means for generating a control signal to control the switching means;
a current detection element having a first end connected to the second end of the switching means and a second end connected to a negative terminal of a power source device to be tested; and
a seriously connected impedance element having a first end connected to a positive terminal of the power source device and a second end connected to the first end of the switching means;
wherein the impedance element has an impedance which is much greater than the intrinsic impedance of the switching means, so that the impedance element takes a major power energy supplied from the power source device, while the switching means only takes a small power energy.

2. The control circuit as claimed in claim 1, wherein the current detection element comprises a resistor connected in serial with the switching means.

3. The control circuit as claimed in claim 1, wherein the switching means comprises a power transistor having a source connected to the positive terminal of the power source device via the impedance element and a drain connected to the current detection element, the power transistor comprising a gate connected to the control signal generating means whereby the power transistor is controlled by the control signal generating means.

4. The control circuit as claimed in claim 1, wherein the seriously connected impedance element comprises a resistor.

5. A control circuit for an electronic load simulation device, comprising a primary control circuit and at least one parallelly connected control circuit, the primary control circuit comprising:
switching means having a first end and a second end, having an intrinsic impedance when conducted;
means for generating a control signal to control the switching means; a current detection element having a first end connected to the second end of the switching means and a second end connected to a negative terminal of a power source device to be tested; and
a seriously connected impedance element having a first end connected to a positive terminal of the power source device and a second end connected to the first end of the switching means;
wherein the impedance element of the primary control circuit has an impedance which is much greater than the intrinsic impedance of the switching means of the primary control circuit, so that the impedance element takes a major power energy supplied from the power source device, while the switching means only takes a small power energy;
each parallelly connected control circuit comprising:
switching means having a first end and a second end, having an intrinsic impedance when conducted;
means for generating a control signal to control the switching means;
a current detection element having a first end connected to the second end of the switching means and a second end connected to the negative terminal of the power source device; and
a seriously connected impedance element having a first end connected to the positive terminal of the power source device and a second end connected to the first end of the switching means;
wherein the impedance element of each parallelly connected control circuit has an impedance which is much greater than the intrinsic impedance of the switching means of the parallelly connected control circuit, so that the impedance element takes a major power energy supplied from the power source device, while the switching means only takes a small power energy.
